(19) United States
(12) Patent Application Publication
(10) Pub. No.: US 2005/0076281 A1
(43) Pub. Date: Apr. 7, 2005

(54) Network terminal that notifies administrator of error

(75) Inventor: Atsushi Kojima, Kasugai-shi (JP)

Correspondence Address: OLIFF & BERRIDGE, PLC, P.O. BOX 19928, ALEXANDRIA, VA, 22320, US

(73) Assignee: Brother Kogyo Kabushiki Kaisha, Nagoya-shi (JP)

(21) Appl. No.: 10/401,569

(22) Filed: Mar. 31, 2003

(30) Foreign Application Priority Data
Apr. 3, 2002 (JP) 2002-101609

(51) Int. Cl. G11C 29/00; G06F 11/00; G01R 31/28

(52) U.S. Cl. 714/736

(57) ABSTRACT

An administrator on a network device performs notification settings on a Web page provided by a network terminal. Information on the notification settings is stored in a storage area provided to the network terminal. When an occurrence or correction of an error is detected at the network terminal, then it is determined whether or not the status of the error meets the notification settings. The network terminal notifies the administrator of the occurrence or the correction of the error by sending an electronic mail only if the status of the error meets the notification settings.

### BACKGROUND OF THE INVENTION

1. Field of the Invention

The present invention relates to a network terminal that notifies an administrator of an error and correction of the error by sending an electronic mail.

2. Description of the Related Art

Conventional network terminals provided on a network notify administrators or users of an error occurred in the network terminals by generating a buzzer sound, displaying an error message on a display, or illuminating an electric sign provided to the network terminals. Some of the network terminals notify the administrators or users of the error only if the status of the error meets a predetermined condition.

There is also proposed a method of notifying such an error by sending an electronic mail to remote devices of the administrators or users. Because different electric mails can be delivered to a plurality of devices even at remote locations, transmitting electronic mails is convenient notification method particularly for remote administrators and users. Using the electronic mail is also advantageous in that a commonly used system can be used and also in that electronic mails enable a communication even among networks divided by rooters or the like.

However, the conventional network terminals that send an electronic mail for notifying the administrators or users of an error (hereinafter referred to—ac “error notification mail”) send such an error notification mail every time an error occurs regardless of whether the error is worth notifying. For example, when sheet jam occurred and a user opened a cover to remove the jammed sheet, then the network terminal sends two error notification mails of “sheet jam” and “cover open”. If the user opens and closes the cover many times to remove the jammed sheet, then the network terminal sends an error notification mail of “cover open” every time the user opens the cover. In this case, when the user comes back to a remote network device from the network terminal after removing the jammed sheet, the user will find the error notification mail of “cover open” delivered to the network device. Then, the user may come over to the network terminal to remove a jammed sheet again although the jammed sheet has already been removed. This is totally unnecessary and waste of time. This problem is caused because the network terminal does not distinguish between “a cover is opened temporarily” and “a cover is left open”. The same problem occurs when, for example, a user opens a sheet feed tray to supplement sheets.

Moreover, although error notification mails of “cover open” and “sheet feed tray open” may be necessary for the administrator, these error notification mails may not be necessary for the users. In this case, the users receive unnecessary error notification mails. This problem is caused because the network terminal sends an error notification mail without selecting receivers of the mail.

### SUMMARY OF THE INVENTION

In view of foregoing, it is an object of the present invention to overcome the above problems and also to provide a network terminal that can notify an administrator of occurrence and correction of an error only when status of the error meets a predetermined notification condition.

In order to attain the above and other objects, the present invention provides a network system including a network terminal and a terminal device connected to the network terminal. The network terminal includes an error detection unit that detects an error, a first memory that stores status of the error, a second memory that stores a notification condition, a judgment unit that judges whether or not the status of the error meets the notification condition, and a notify unit that notifies the terminal device of the status of the error only when the judgment unit judges that the status of the error meets the notification condition.

There is also provided a network terminal connected to at least one terminal device. The network terminal includes an error detection unit that detects an error, a first memory that stores status of the error, a second memory that stores a notification condition, a judgment unit that judges whether or not the status of the error meets the notification condition, and a notify unit that notifies the terminal device of the status of the error when the judgment unit judges that the status of the error meets the notification condition.

Further, there is provided a notifying method of notifying a terminal device of an error. The notifying method includes the steps of a) detecting an error occurred at a network terminal, b) storing status of the error into a first memory, c) judging whether or not the status of the error meets a notification condition stored in a second memory, and d) notifying the terminal device of the status of the error when the status of the error is judged to meet the notification condition in the step c).

### BRIEF DESCRIPTION OF THE DRAWINGS

In the drawings:

FIG. 1 is an explanatory diagram showing a basic configuration of a network according to an embodiment of the present invention;

FIG. 2 is an explanatory block diagram showing a configuration of the network according to the embodiment of the present invention;

FIG. 3 is a block diagram of a printer and an adinistrator's terminal on the network of FIG. 2:

FIG. 4 is a flowchart representing a notification setting process according to the embodiment of the present invention;

FIG. 5 shows a printer basic information setting screen displayed on a monitor of the administrator's terminal;

FIG. 6 shows a notification setting screen displayed on the monitor of the administrator's terminal;

FIG. 7 shows a notification setting screen displayed on the monitor of the administrator's terminal;

FIG. 8 is a view schematically showing notification setting information stored in a notification setting information storage area provided to the printer of FIG. 3;

FIG. 9 is a table showing relationship among a notification condition code, a notification condition, and a quantity;

FIG. 10 is a view schematically showing status information of each administrator stored in an administrator-status-information storage area provided in the printer;

FIG. 11(a) is an example of an error notification mail;

FIG. 11(b) is an example of a restoration notification mail;

FIG. 12 is a view schematically showing notification mail preparation lists stored in a list storage area provided in the printer;

FIG. 13 is a flowchart representing a notification process according to the embodiment of the present invention;

FIG. 14 is a flowchart representing a list preparation process executed in s13 of rig. 13;

FIG. 15 is a flowchart representing a list-preparation sub-process executed in S24 of FIG. 14:

FIG. 16 is a flowchart representing a notification mail preparation/transmission process performed in S14 of FIG. 13;

FIG. 17 is a flowchart representing an error continuation detection process according to the embodiment of the present invention;

FIG. 18 is a flowchart representing a process executed in S63 of FIG. 17;

FIG. 19 is a flowchart, representing a list preparation process executed in 877 of FIG. 18;

FIG. 20 shows a notification setting screen displayed on the monitor of the administrator's terminal according to a notification setting software installed in the administrator's terminal; and

FIG. 21 shows a notification setting screen displayed on the monitor of the administrator's terminal according to the notification setting software.

### DETAILED DESCRIPTION OF THE PREFERRED EMBODIMENT

Next, an embodiment of the present invention will be described with reference to the accompanying drawings.

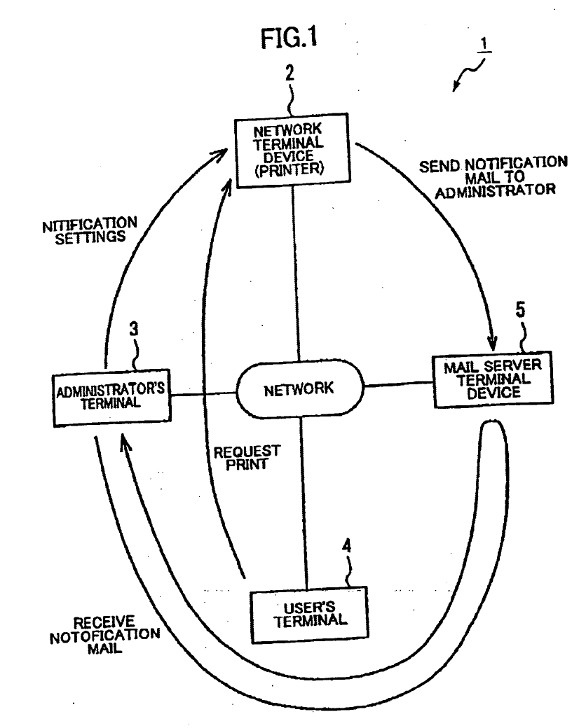

FIG. 1 shows a basic configuration of a network according to the present embodiment. As shown in FIG. 1, a network 1 includes a printer 2, an administrator's terminal 3, a user's terminal 4, and a mail server terminal device 5.

The administrator's terminal 3 and the user's terminal 4 are both well-known personal computers provided with printer control software (printer driver) for utilizing the printer 2. The administrator's terminal 3 is further provided with electronic mail software for sending and receiving electronic mails via the network 1 and a Web browser for browsing a Web page. The administrator's terminal 3 performs various settings of the printer 2, such as notification settings, by using the Web browser in a manner described later. The user's terminal 4 sends a print command to the printer 2 via the network 1, requesting the printer 2 to perform printing. The mail server terminal device 5 is a well-known personal computer including an SMTP server for managing transmission of an electronic mail and a POP server for managing reception of an electronic mail, and manages exchanges of electronic mails among the devices on the network 1.

As will be described later in detail, when an error occurs or when an error is fixed in the printer 2, the printer 2 prepares a notification mail based upon the notification settings and transmits the notification mail to the administrator's terminal 3 via the mail server terminal device 5.

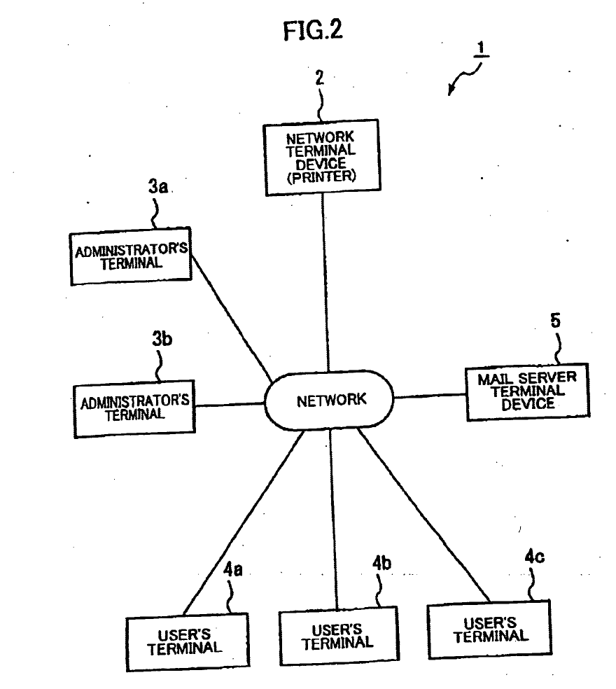

As shown in FIG. 2, the network 1 of the present embodiment includes two administrator's terminals 3a and 3b and three user's terminals 4a, 4b, and 4c.

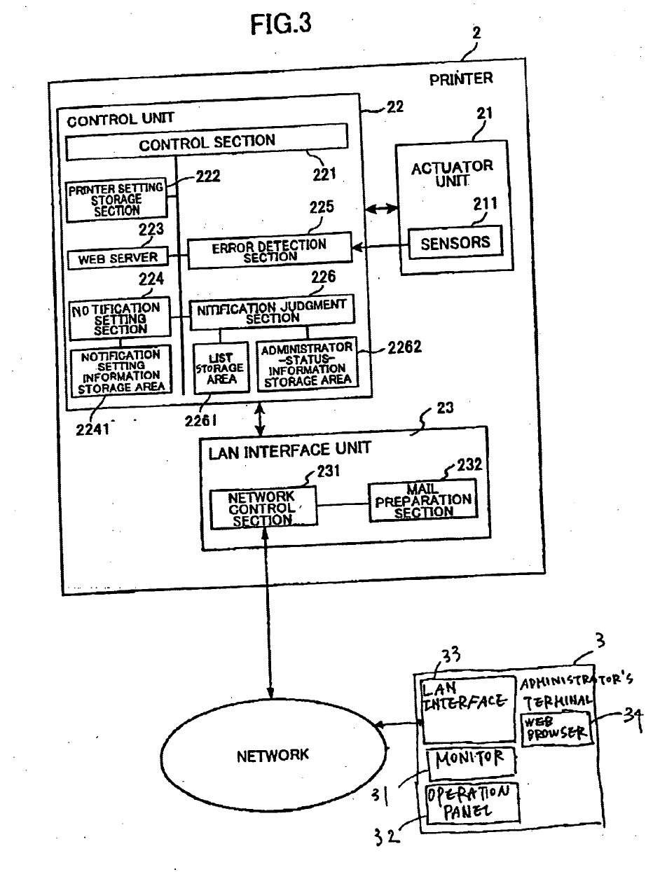

Next, functions of the printer 2 will be described with reference to FIG. 3. The printer 2 includes an actuator unit 21, a control unit 22 for performing an overall control of the printer 2, and a LAN interface unit 23 for managing communication between the printer 2 and the network 1.

The actuator unit 21 includes a print mechanist, a paper feed mechanism, and other mechanisms (not shown), each provided with a corresponding one of sensors 211. Each sensor 221 outputs a detection signal relating to status of the corresponding mechanism. The control unit 22 includes a control section 221, a printer setting storage section 222, a Web server 223, a notification setting section 224, an error detection section 225, and a notification judgment section 226.

The control section 221 is for processing a command or data transmitted from the administrator's terminal 3 and the user's terminal 4 via the network 1 and for controlling the sections 222-226 and the actuator unit 21 based on the command or data. The printer setting storage section 222 is for storing various settings of the printer 2. The Web server 223 is for generating a Web page and for providing the administrator's terminal 3 with the Web page when requested. The Web page ic used when an administrator sets various settings relating to error notification. The notification setting section 224 performs settings for the error notification through the administrator's terminal 3. The notification setting section 224 also manages a notification setting information storage area 2241. The error detection section 225 constantly monitors the output from the sensors 211 and detects occurrence and correction of errors in the mechanisms.

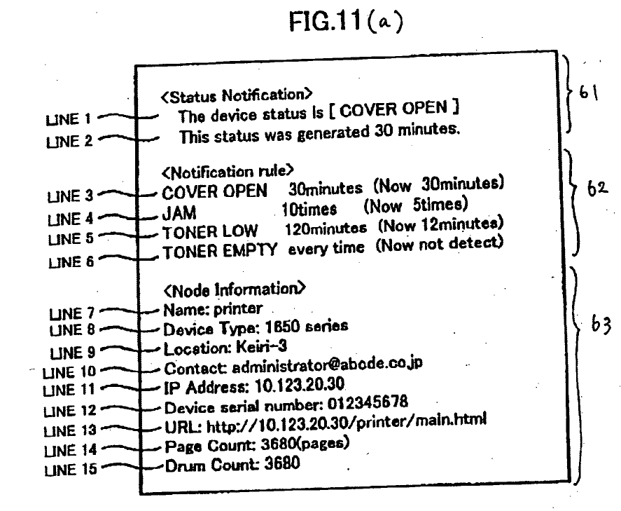

The notification judgment section 226 judges whether or not to notify the occurrence and correction of errors detected by the error detection section 225 based on information stored in the notification setting information storage area 2241, and if the notification is judged necessary, the notification judgment section 226 executes a necessary process to be described later. Also, the notification judgment section 226 manages a administrator-status-information storage area 2262, which stores status information for each administrator (FIG. 10). The status information is indicating current status of each error, cleared when a main power of the printer 2 is turned ON, and updated as needed when an error occurs and when the error is fixed. Details will be described later.

The LAN interface unit 23 includes a network control section 231 and a mail preparation section 232. The network control section 231 is for controlling communication between the network 1 and the printer 2. Upon reception of a mail-preparation instruction, the mail preparation section 232 prepares a notification mail, updates the status information stored in the administrator-status-information storage area 2262, and sends the notification mail under the control of the network control section 231.

Note that the control unit 22 and the LAN interface unit 23 are realized by well-known circuit configurations including a central processing unit (CPU), a random access memory (RAM), a read only memory (ROM), an input/output (I/O) interface, a serial interface, and the like. The sections 221-226 and 231-232 in the control unit 22 and the LAN interface unit 23 are all realized by programs.

As shown in FIG. 3, the administrator's terminal 3 includes a monitor 31, an operation panel 32, a LAN interface 33, and a Web browser 34.

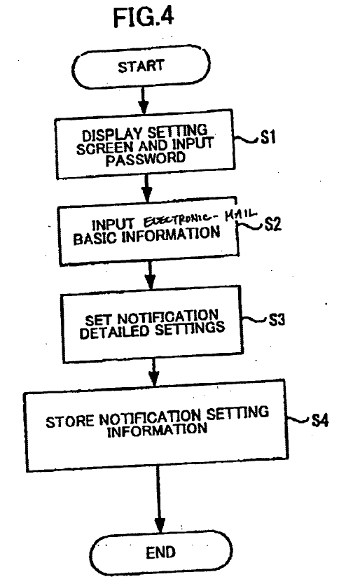

Next, a notification setting process executed by the notification setting section 224 will be described with reference to FIGS. 4 to 9. The notification setting process is for performing electronic-mail basic settings and notification detailed settings (collectively referred to as “notification settings”). The notification detailed settings are prepared for each administrator.

The notification setting process stars when the administrator accesses the printer 2 using the Web program installed on the administrator's terminal 3. When the process starts, the notification setting section 224 provides a Web page to the administrators terminal 3, so that the Web page is displayed on the monitor 31, prompting the administrator to input a password (S1). That is, unauthorized person is prohibited from setting or changing the notification settings.

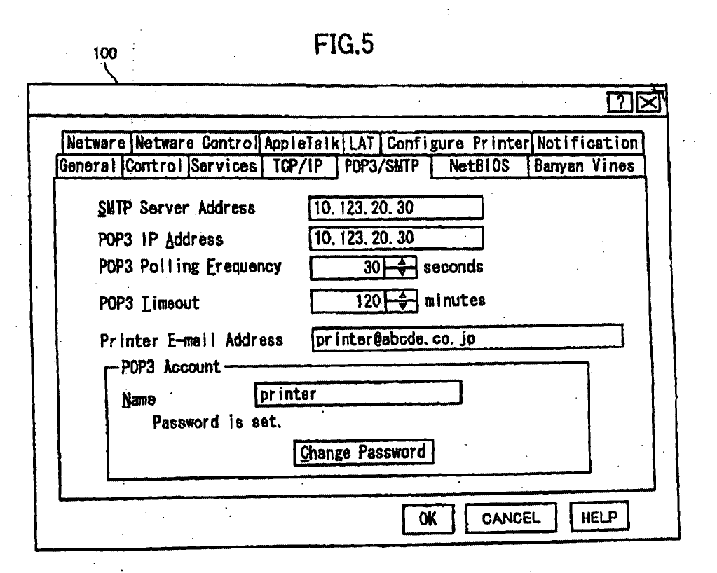

After the administrator inputs a right password through the operation panel 32 in S1, an electronic-mail basic information setting screen 100 shown in FIG. 5 is displayed on the monitor 31, prompting the administrator to input electronic-mail basic information relating to the mail server terminal device 5 necessary for sending and receiving an electronic mail (S2). In the example shown in FIG. 5. “10.123.20.30” was input as a Simple Mail Transfer Protocol (SMTP) Server Address, “10.123.20.30” was input as a Post Office Protocol Version 3 Internet Protocol Address (POP3 IF Address), and “printer@abcde.co.jp” was input as a Printer E-mail Address. In this embodiment, the administrator inputs an electronic mail address of the printer 2 as the Printer E-mail Address, since the printer 2 is the sender of a notification mail. Thus input electronic-mail basic information is stored in the printer setting storage section 222.

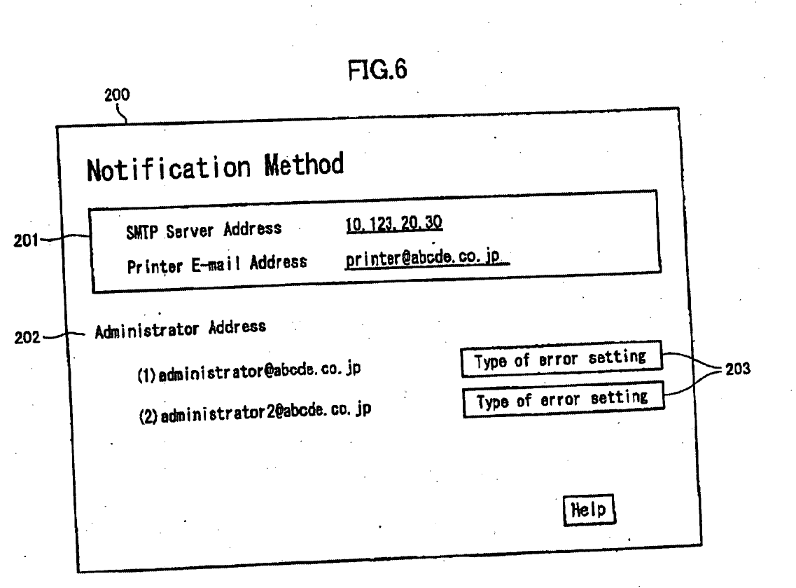

Subsequently, a notification setting screen 200 shown in FIG. 6 is displayed on the monitor 31, prompting the administrator to perform notification detailed settings (S3). This screen 200 is titled “Notification Method”, and an enclosed upper section 201 displays the printer basic information stored in S2. The administrator performs the notification detailed settings in the following manner.

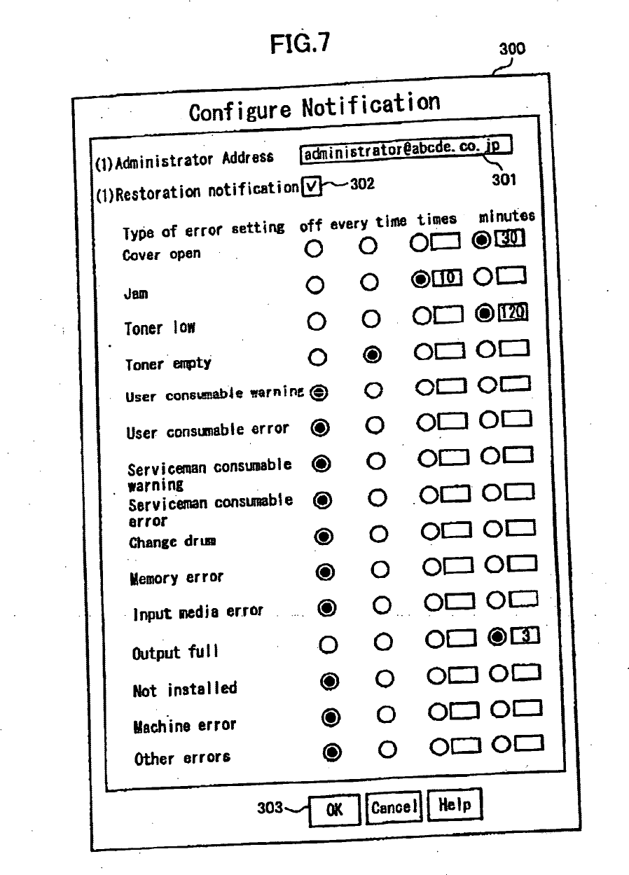

First, the administrator presses one of “Type of error setting” buttons displayed below the enclosed upper section 201, so that a notification setting screen 300 shown in FIG. 7 is displayed on the monitor 31. This screen 300 is titled “Configure Notification”. Next, the administrator inputs an electronic mail address of his/her own in a box 301 right to the “(1) Administrator Address” on a first line. A notification mail is sent to this electronic mail address. Then, the administrator indicates whether or not he or she wishes to receive a restoration notification mail which is sent when the error is fixed, by using a check box 302 right to “(2) Restoration notification” on a second line. That is, if the administrator wishes to receive the restoration notification mail, the administrator checks the check box 302. On the other hand, it not, the administrator leaves the check box 302 unchecked.

Subsequently, the administrator selects a notification condition for each error type. In this embodiment, there are 15 error types as listed in the notification setting screen 300 of FIG. 7, and four notification conditions, namely “off”, “every time”, “times”, and “minutes”, are prepared for each error type. The administrator can select one of the four notification conditions by using radio buttons. Here, if “off” is selected, then an error is not notified. If “every time is selected, then an error is notified every time the error occurs. If “times” is selected, then administrator is requested to indicate a desired number of times by inputting a corresponding number in a box besides the radio button. If “times” is selected in this manner, an error is notified once every the number of times. In the example of FIG. 7, a “Jam” error is notified only if the “Jam” error has occurred 10 times. If “minutes” is selected, then the administrator is requested to indicate a desired duration of time by inputting a corresponding number into a box besides the radio button. If “minutes” is selected in this manner, an error is notified only if the error has not been fixed for predetermined minutes or more. In the example of FIG. 7, a “Cover open” error is notified only if the “Cover open” error has not been fixed for 30 minutes or more.

In this embodiment, the above-described notification detailed settings can be set for up to two administrators, and the address input to the box 301 is listed in an Administrator Address area 202 of FIG. 6. In the example of FIG. 6, two electronic mail addresses are listed; a first one is Administrator@abcde.co.jp, and a second one is Administrator 2@abcde.co.jp.

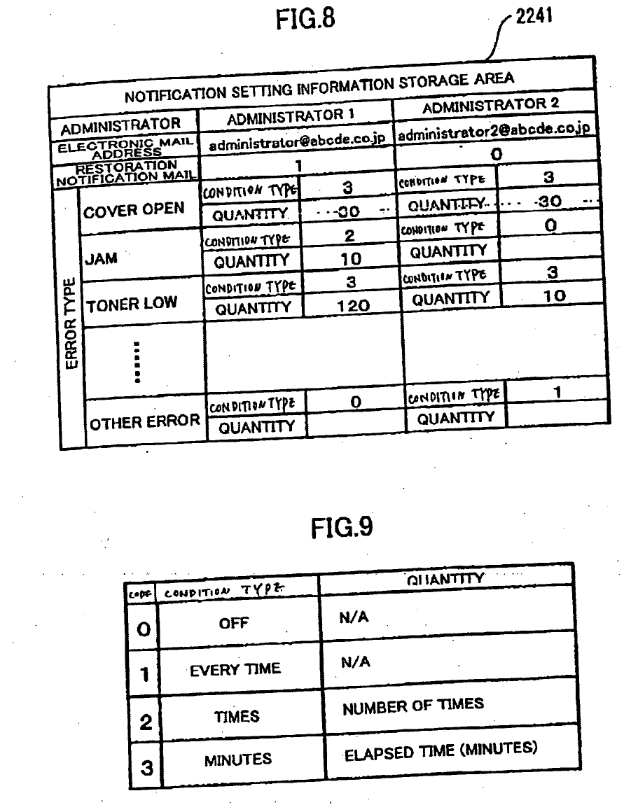

When the administrator selects an “OK” button 303 on the notification setting screen 300 (FIG. 7), then the information inputted in the notification setting screen 300 is stored as a notification setting information (FIG. 8) in the notification setting information storage area 2241 (FIG. 3) of the printer 2 (S4).

Here, the notification setting information stored in the notification setting information storage area 2241 will be described with reference to FIG. 10. As shown in FIG. 10, the notification setting information storage area 2241 includes an “electronic mail address” area for storing administrators electronic mail addresses, which are destinations of notification mails. In a “restoration notification mail”, area, a code of “1” or “0” is stored. “1” is stored if the check box 302 (FIG. 1) has been checked by the administrator, and “0” is stored if not. That is, the code in the % restoration notification mail” area indicates whether or not the corresponding administrator wishes to receive a restoration notification mail. An “error type” area includes a “condition type” area and a “quantity” area for each of the fifteen error types. In the “condition type” area, one of four notification-condition codes “0”, “1”, “2”, “3” is stored. These notification-condition codes “0”, “1”, “2”, “3” correspond to the above-described notification conditions of “off”, “every time”, “times”, and “minutes” (FIG. 7), respectively.

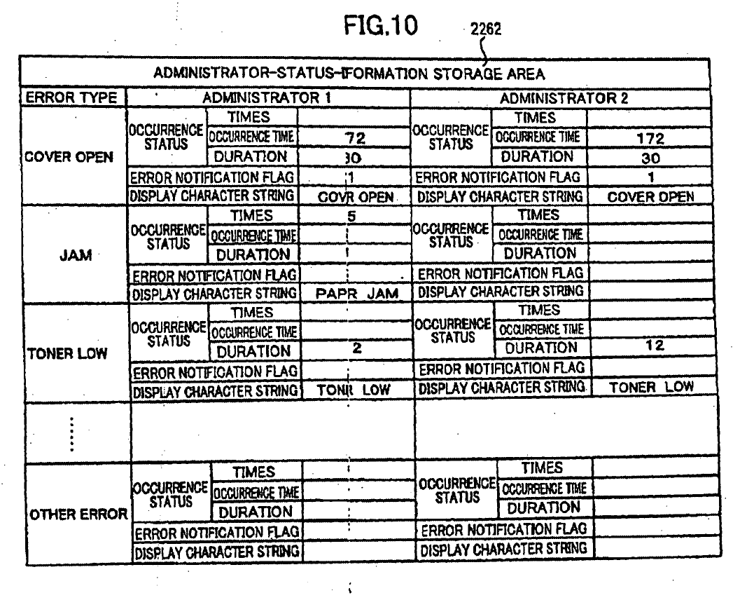

The “quantity” area is not used if the notification-condition code of “00 or “11 is stored in a corresponding condition type, area. If the notification-condition code of “2” is stored in the “condition type.” area, then a number stored in the corresponding “quantity” area indicates the number of times, which has been selected in the notification setting screen 300. If the notification-condition code of “3”is stored in the “condition type, area, then a number stored in the corresponding “quantity” area indicates the minutes, which has been selected in the notification setting screen 300. FIG. 9 shows the correspondence of the notification-condition code, the notification condition, and the quantity.

For example, if the condition type is “2” and the quantity is “0”, then, this means that an error is notified once every ten times. If the condition type is “3” and the quantity is “30”, then, this means that an error is notified if the error has not been fixed for 30 minutes or more.

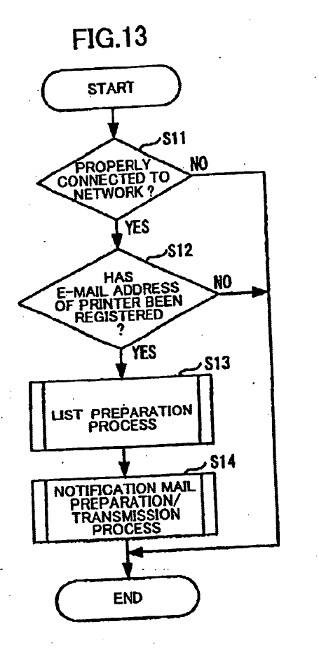

Next, a notification process for sending a notification mail to the administrator's terminal 3 will be described with reference to the flowcharts of FIGS. 13 to 15. This notification process is executed by the notification judgment section 226 and starts when occurrence or correction of an error is detected by the error detection section 225. In this process, first, it is determined whether or not the printer 2 is properly being connected to the network 1 and in a condition capable of sending an electronic mail (S11). If the printer 2 is not properly being connected to the network 1 (S11:NO), then the present process ends. On other hand, if the printer 2 is properly being connected to the network 1 (S11:YES), then it is determined whether or not an electronic mail address of the printer 2 is registered (S12). Here, the electronic mail address of the printer 2 is displayed on the notification setting screen 200 shown in FIG. 6 in the above-described manner.

If it is determined in 512 that the electronic mail address of the printer 2 is not being registered (S12:NO), the present process ends. On the other hand, if it is determined in S12 that the electronic mail address of the printer 2 is being registered (S12:YES), then a list-preparation process (S13) and a notification mail preparation/transmission process (S14) are executed. Afterwards, the present process ends. The list-preparation process executed in S13 and the notification mail preparation/transmission process executed in S14 will be descried in detail next.

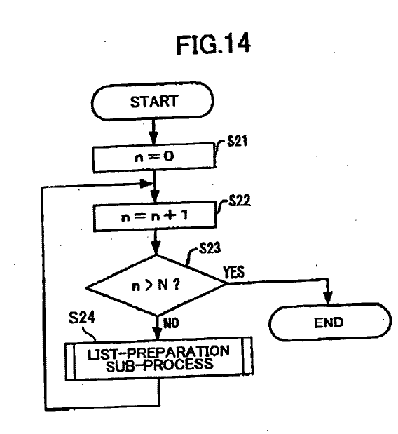

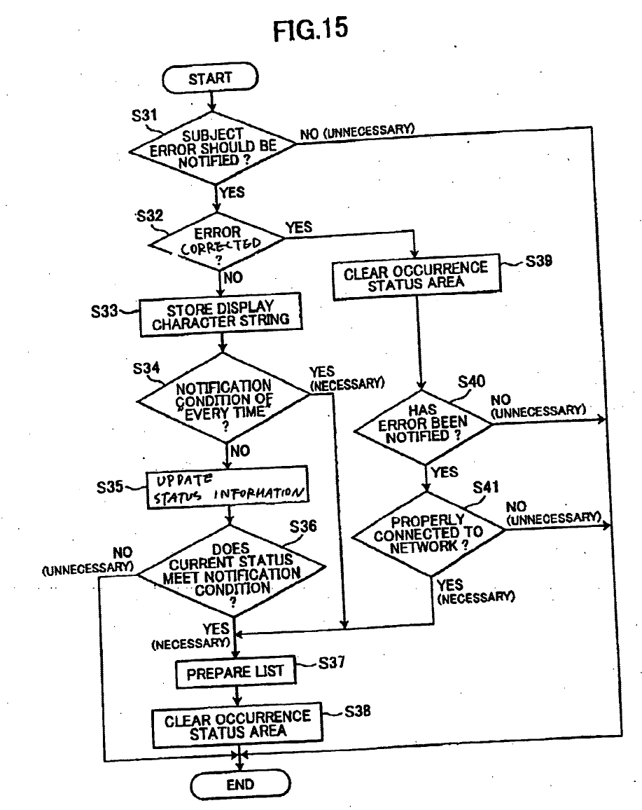

First, the list-preparation process will be described with reference to the flowchart of FIGS. 14 and 15. In this list-preparation process, a notification mail preparation list is prepared if notification is determined necessary.

First, an administrator-counter value n is initialized to 0 (S21). Then, the administrator-counter value n is incremented by 1 (S22). It is determined whether or not the administrator-counter value n is greater than a value N, which indicates a number of the administrators. The value N will be “1” if one administrator is registered, and “2” if two administrators are registered, and “0” if no administrators is registered. If the administrator-counter value n is not greater than the value N (S23:NO), then this means that a process has not completed for all the administrators. Then, a list-preparation sub-process is executed for n^{th} administrator (S24), and the process returns to S22. On the other hand, if the administrator-counter value n is greater than the value N (S23:YES), this means that the process has completed for all of the N-numbered administrators, so that the process ends.

FIG. 15 shows a flowchart representing the list-preparation sub-process executed in S24. In this process, it is determined whether or not the nt administrator wishes to receive a notification mail relating to a subject error (S31). This determination is made by referring to the notification setting information stored in the notification setting information storage area 2241 (FIG. 8). That is a, if the notification-condition code stored in a % condition types area for the subject error type is “0”, then, this means that notification is unnecessary. Therefore, a negative determination is made in S31 (S31:NO), and the present process ends. On the other hand, if the notification-condition code stored in the “condition type” area for the subject error type is “1”, “2”, or “3”, then a positive determination is made in 531 (S31:YES), and the process proceeds to S32.

In 532, it is determined whether or not the notification process is currently being executed because the error detection section 225 has detected the correction of the subject error. If so (S32:YES), then the process proceeds to S39. On the other hand, if not (S32:NO), this means that the notification process is being executed because the error detection section 225 has detected the occurrence of the subject error. In this case, a name of the subject error type is stored in a corresponding “display character string, area of the administrator-status-information storage area 2262 (FIG. 10) (S33). Then, it is determined whether or not the notification condition for the subject error type is “every time” (S34) with reference to the notification setting information (FIG. B). More specifically, if the notification-condition code stored in the condition type” area for the subject error type in the notification setting information storage area 2241 (FIG. 8) is “1” indicating “every time” (S34:YES), then, this means that notification is necessary, and the process proceeds to S37. On the other hand, if the notification-condition code stored in the “condition type” area for the subject error type is not “1”, but “2” or “3”, (S34:NO), then, the process proceeds to S35.

In S35, status information on the subject error stored in the administrator-status-information storage area 2262 (FIG. 10) is updated according to the notification condition information (FIG. 8). Specifically, if the notification-condition code in the “condition type” area for the subject error type in the notification setting information storage area 2241 (FIG. 8) is “2”, then the value stored in a “times” area for the subject error type of the administrator-status-information storage area 2262 (FIG. 10) is incremented by 1. On the other hand, if the notification-condition code in the condition type” area for the subject error type in the notification setting information storage area 2241 (FIG. 8) is “2”, then it is determined whether or not an occurrence time is currently stored in an “occurrence time” area for the subject error of the administrator-status-information storage area 2262 (FIG. 10). If not, the present time is stored in the “occurrence time” area, and also “0” is stored in a corresponding “duration” area. On the other hand, if so, then a time duration is calculated by deducting the occurrence time currently stored in the occurrence time” area from the present time, and the calculated duration of time is stored in the “duration” area. Here, the “present time” is time elapsed since the main power of the printer 2 is turned ON.

In the example of FIG. 8, with respect to the error type of “JAM” for an administrator 1, the notification-condition code is “2” and the quantity is “10”. This means that the error “JAM” is notified to the administrator 1 once every 10 times. On the other hand, as shown in FIG. 10, the value in the “times” area for the error type of “JAM” is “5”. This indicates that the “Jam” error has occurred five times so far. Similarly, with respect to the error type of “Cover open” in the administrator 1, the notification-condition code is “3” and the quantity is “30”. This means that the “Cover open” error is notified to the administrator 1 only if the cover is left open for 30 minutes or more. On the other hand, as shown in FIG. 10, the values in the occurrences area and the “duration” area for the error type of “Cover opens are “172” and “30”, respectively. This indicates that the “cover open” error has occurred 172 minutes after the main power of the printer 2 has been turned ON, and that the cover is left open for 30 minutes. The value “30” in the “duration” area is calculated by subtracting the occurrence time of 172 from the present time of 202 (202−172=30).

After the above-described process in S35 completes, it is determined whether or not the current status of the subject error, which is indicated by the status information (FIG. 10), meets the corresponding notification condition (S36). If not (S36:NO) then, this means that the notification is unnecessary, and the present process ends. On the other hand, if so (S36:YES), this means that the notification is necessary, and the process proceeds to S37 to prepare a notification mail preparation list.

In S39, the value stored in the “occurrence status” area (“times” area, “occurrence time” area, and “duration” area) and also the character string stored in the “display character string” area for the subject error type in the administrator-status-information storage area 2262 (FIG. 10) are erased. Then, it is determined whether or not an error notification mail for the subject error, which has just been fixed, has been transmitted to the subject administrator based on the status information stored in the administrator-status-information storage area 2262 (FIG. 10) (S40). That is, if a flag stored in a corresponding terror notification flag, area in the administrator-status-information storage area 2262 (FIG. 10) is ¢1”, this indicates that the error notification mail has been transmitted (S40:YES). On the other hand, if the flag is not “1”, this means that the error notification mail has not been transmitted (S40:NO).

If it is determined in S40 that the error notification mail has not been transmitted (S40:NO), then this means notification is unnecessary, and the present process ends. On the other hand, if it is determined in S40 that the error notification mail has been transmitted (S40:YES), then it is determined in S41 whether or not a restoration notification mail is required with reference to the notification setting information (FIG. 8). More specifically, if the value stored in the “restoration notification mail” area for the subject administrator in the notification setting information storage area 2241 is “1”, this means the restoration notification mail is required. On the other hand, if the value is “0”, then this means the restoration notification mail is not required.

If it is determined in S41 that the restoration notification mail is not required (S41:NO), then this means notification is unnecessary, and so the process ends. On the other hand, if it is determined in S41 that the restoration notification mail is required (S41:YES), then this means notification is necessary, and the process proceeds to S37 so as to prepare a notification mail preparation list.

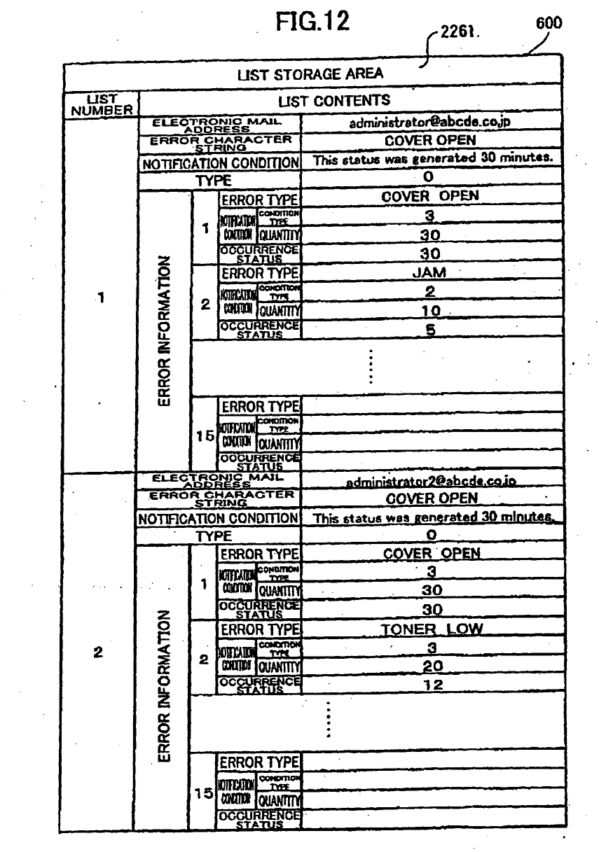

As described above, the mail preparation list is prepared only when the notification is determined necessary. FIG. 12 shows an example of the notification mail preparation list 600. As shown in FIG. 12, the notification mail preparation list 600 includes “Electronic mail address” area, “Error character string” area, “Notification condition” area, “Mail type” area, and “Error information” area.

The “Electronic mail address” area is for storing a corresponding administrator's electronic mail address. The “Error character string” area is for storing an error character string of the subject error type, such as “COVER OPEN”, “JAM”, or “TONER LOW”. The “Notification condition” area is for storing a character string, which depends on whether a notification mail is an error notification mail notifying an occurrence of the subject error or a restoration notification mail notifying a correction of the subject error. If the notification mail is the error notification, then a character string indicating a notification condition, which the current status of the subject error meets, is stored. In the example of FIG. 12, “This status was generated 30 minutes” is stored. On the other hand, if the notification mail is the restoration notification mail, then a predetermined message, such as “The device has been recovered from this status”, is stored.

The “Mail type” area is for storing a value of either “0” or “1”. If the notification mail is the error notification mail, then the value of “1” is stored. If the notification mail is the restoration notification mail, then the value of “0” is stored. The “Error information” area is for storing information on errors which the administrator whishes to receive error notification mails of. That is, in the “Error information” area, information on one or more of 15 error types with the notification condition code of “1”, “2”, or 03” is stored based on the notification setting information (FIG. 8).

More specifically, the “Error information” area includes an “error type” area, a “condition type” area, a “quantity” area, and an “occurrence status” area. In the “error type” area, a name of the error type, such as “COVER OPEN”, “JAM”, or “TONER LOW”, is stored. In the “condition type” and “quantity” areas, the same values stored in the “condition type” and “quantity” areas of the notification setting information storage area 2241 (FIG. 8) are stored. A value stored in the “occurrence status” area is determined in accordance with the value stored in the “condition type” area. That is, when the value in the “condition type” area is “1”, then a value “1” is stored into the occurrence status area if the display character string is currently stored in the corresponding display character string area in the administrator-statue-information storage area 2262 (FIG. 10), and a value ON is stored into the “occurrence status” area if the display character string is net currently stored. In other words if the display character string is being stored in the administrator-status-information storage area 2262, this means that the corresponding error has occurred, so that the value of “1” indicating the occurrence of the error is stored. On the other hand, if the display character string is not being stored in the administrator-status-information storage area 2262, this means that the corresponding error has not occurred, so that the value of “0” indicating that the error has not occurred is stored.

On the other hand, when the value stored in the “condition type” area is “2”, then the value stored in the corresponding “times” area of the administrator-status-information storage area 2262 is stored into the “occurrence status” area. When the value stored in the “condition type” area is “3”, then the value stored in the “duration” area of the administrator-status-information storage area 2262 is stored into the “occurrence status” area.

In this manner, the notification mail preparation list 600 is prepared. Then, thus prepared notification mail preparation list 600 is stored into the list storage area 2261 (FIG. 3).

After the process in S37 completes, the values in the “occurrence status” area (“times” area, “occurrence time” area, and “duration” area) for the subject error in the administrator-status-information storage area 2262 (FIG. 10) are erased (S38). Then, the current process ends.

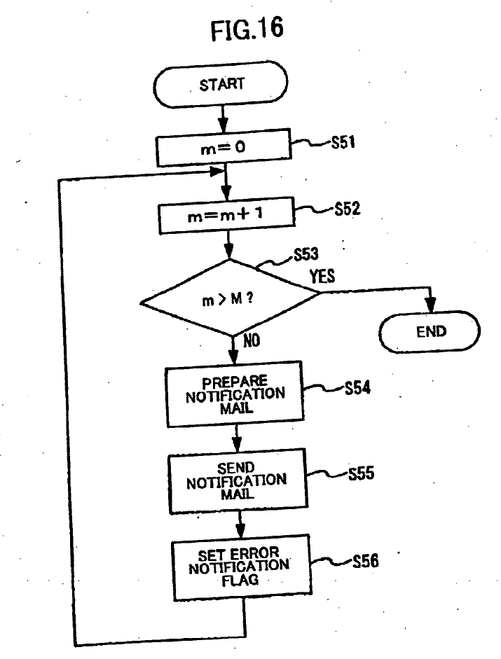

Nest, the notification mail preparation/transmission process executed in S14 of FIG. 13 will be described with reference to the flowchart of FIG. 16. In this process, a notification mail is prepared based on the notification mail preparation list 600 and transmitted to the admnistrator's terminal 3.

As shown in FIG. 16, first, a list counter value m is initialized to “0” (S51) and incremented by 1 (S52). It is determined whether or not the list counter value m is greater than a value M, which indicates a number of notification mail preparation lists 600 stored in the list storage area 2261 (FIG. 12) (S53). In the example of FIG. 12, there are two notification mail preparation lists 600 stored in the list storage area 2261. If the list counter value m is not greater than the value M (S53:NO), then, a notification mail is prepared based upon a m^{th} notification mail preparation list 600 (S54).

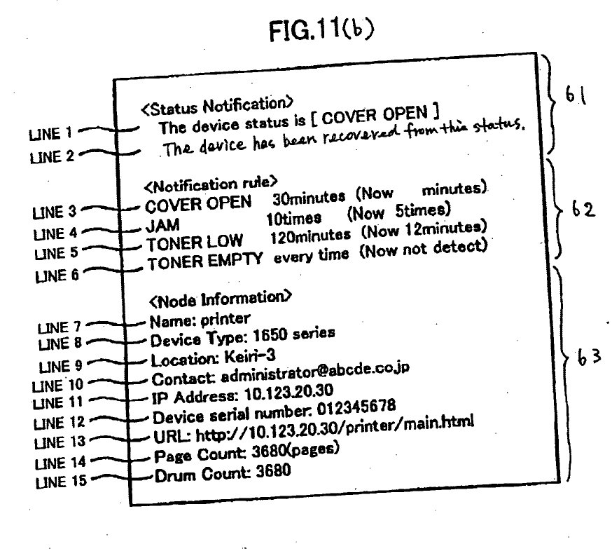

FIG. 11(a) shows an example of an error notification mail, and FIG. 11(b) shows an example of a restoration notification mail. As shown in FIGS. 11(a) and 11(b), a test of the notification mail includes “Status Notification” section 61, “Notification rule” section 62, and “Node Information” section 63. In the process of S54, first the character string stored in the “error character string” area of the notification mail preparation list 600 (FIG. 12) is written in parentheses [ ] on a first line. In the example of FIG. 11(a), “COVER OPEN” is written in the parentheses. Next, the information stored in the “notification condition” area in the notification mail preparation list 600 (FIG. 12) is written in a second line. In the example of FIG. 11(a), “This status was generated 30 minutes” was written in the second line. That is, in this example, an error “COVER OPEN” has occurred and notified because “This status was generated 30 minutes”.

Next, information on errors stored in the “error information” area of the notification mail preparation list 600 is written in the “Notification rule” section 62 in the following manner. That is, an error type, a setting condition, and an occurrence status are written in this order in a third line based on the first error information (error information 1) of the notification mail preparation list 600 (FIG. 12). An error type, a setting condition, and an occurrence status are written in this order in a fourth line based on the second error information (error information 2) of the notification mail preparation list 600 (FIG. 12). In the similar manner, information is written in fifth and subsequent lines based on the notification mail preparation list 600.

In the example of FIG. 12, with respect to the first error information of the first notification mail preparation list 600. “COVER OPEN” is being stored in the error “condition type” area. 3 in the “condition type” area and “30” in the “quantity” area together indicate that an error should be notified if an error has not been corrected for 30 minutes or more. “30” in the “occurrence status” area indicates that the error has not been corrected for 30 minutes. Hence, as shown in FIG. 11(a), “COVER OPEN 30 minutes (Now 30 minutes)” is written in the third line. Also, in the example of FIG. 12, the error type of the second error information is “JAM”. The condition type of “2” and the quantity of “10” indicates that an error should be notified once every 10 times. “5” in the “occurrence status” area indicates that the error has occurred five times so far. Hence, as shown in FIG. 11(a), “JAM 10 times (Now 5 times)” is written in the fourth line. In this manner, the “Notification rule” section 62 is prepared.

Here, the “Notification rule” section 62 of the example of FIG. 11(a) notifies the administrator of the following matter. That is, the notification condition for “Cover open” error is “30 minutes”, and 30 minutes has elapsed since “Cover open” error has occurred without the error being corrected. The notification condition far “Jam” error is “ten times”, and the “Jam” error has occurred five times so far. The notification condition for “Toner low” error is 120 minutes, and 12 minutes has elapsed since the “Toner low” error has occurred without the error being corrected. The notification condition for “Toner empty” error is “every time”, and the error has not occurred.

Subsequently, the “Node Information” section 63 is prepared based on the electronic-mail basic information that has been input through the basic information setting screen 100 (FIG. 5) and on printer status information of the printer 2 indicating a number of total print pages and the like. The printer basic information and the printer status information are both stored in the printer setting storage section 222.

In the “Node Information” section 63, an electronic mail address of the administrator is written on the tenth line next to “Contact”. Although the electronic mail address is written on the tenth line in this example, any other text indicating a contact information of the administrator could be written. An IP Address of the printer 2 is written on the eleventh line. Here, the IP address is a specific number assigned to a terminal connected a network. On the thirteenth line, a Uniform Resource Locator (URL), which is used for acquiring the Web page of the printer 2 (the basic information setting screen 100 and the like) using the Web browser is written. In this manner, the notification mail is prepared.

After the notification mail has been prepared in S54, the notification mail is transmitted to the administrator's terminal 3 as a destination via the mail server terminal device 5 (S55). Thus transmitted notification mail is received by the administrator's terminal 3 at the LAN interface 3. Then, “1” or “2” is stored in the “error notification flag” area of the administrator-status-information storage area 2262 (FIG. 10) (S56). Specifically, if the notification mail transmitted in S55 was an error notification mail, then “1” is stored. If the notification mail transmitted in S55 was a restoration notification mail, then 2 is stored. Storing either “1” or “2” into the “error notification flag” area in this manner enables the above-described determination in S40 (FIG. 15) as to whether or not an error notification mail has been transmitted. Then, the process returns to 352, wherein the list counter value m is incremented by 1. If the list counter value m is determined greater than the value M (S53:YES), then the present process ends. If the list counter value m is not greater than the value M (S53:NO) then the process proceeds to S54 to repeat the above process for the subsequent notification mail preparation list 600.

Next, an error continuation detection process for detecting a continuation status of an error will be described.

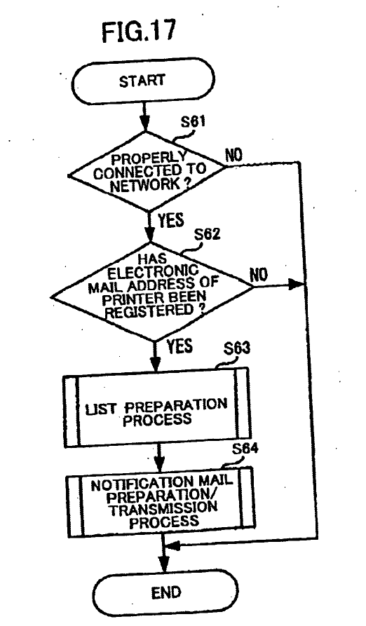

The error continuation detection process shown in FIG. 17 is repeatedly executed by the notification judgment section 226 every ten seconds during operation of the printer 2. Because the processes in S61-S62 and S64 are the same as those in S11-S12 and S14 of FIG. 13, description thereof will be omitted, and only explanation for a process in 563 will be provided.

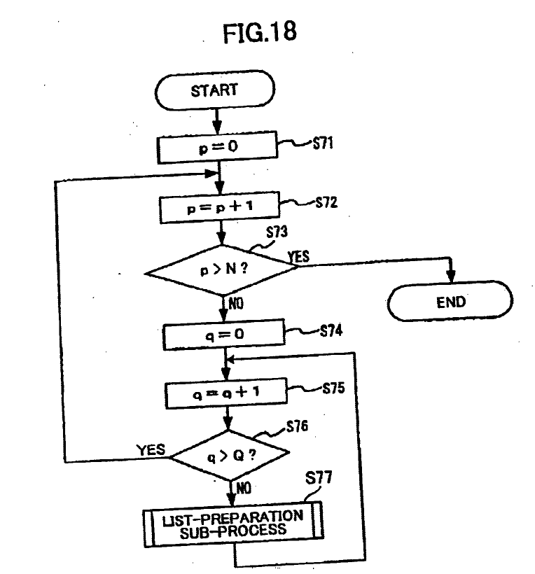

FIG. 18 is a flowchart representing the process executed in S63 of FIG. 17. This process is for preparing a notification mail preparation list 600 for an unfixed error whose notification condition is “minutes”. When this process starts, first, an administrator counter value p is initialized to wok (S71) and then incremented by 1 (S72). It is determined whether or not the administrator counter value p is greater than the value N, which indicates a number of the registered administrators (S73). If the administrator counter value p is greater than the value N (S73:YES), this means that the process has completed for all the administrators. Them, the process ends. On the other hand, if the administrator counter value p is not greater than the value N (S73:NO), this means that the process has not completed for all the administrators. Then, an error counter value q is initialized to “0” (S74) and incremented by 1 (375). It is determined whether or not the error counter value q is greater than a value 0, which indicates the number of the error types, which is 15 in this example (S76). If so (S76:YES), this means that the process has completed for all the error types, and the process returns to S72. On the other hand, if not (S76:NO), this means that the process has not completed for all the error types. Then, a list preparation process is executed (S77), and the process returns to S75.

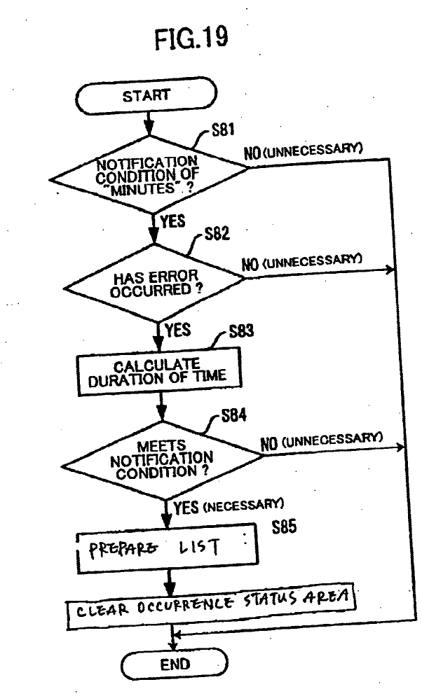

Detailed description of the list preparation process executed in S77 will be provided with reference to the flowchart of FIG. 19.

First, with reference to the notification setting information (FIG. 8), it is determined whether or not a notification-condition code stored in the “condition type” area for a subject error type (q^{th} error type) of a subject administrator (p^{th} administrator) is “3” indicating the notification condition of “minutes” (S81). If not (S81:NO), then this means notification is unnecessary, so that the process ends. On the other hand, if so (S81:YES), then, it is determined whether or not the subject error has occurred (that is, the subject error has occurred and not been fixed yet) with reference to the status information stored in the administrator-statue-information storage area 2262 (FIG. 10) (582). That is, if any value is stored in the corresponding “occurrence time” area, then this indicates that the error bas occurred. On the other hand, if no value is stored in the corresponding % “occurrence time” area, then this means that the error has not occurred (that is, the error has not occurred at all or the error has already fixed).

If it is determined in S82 that the error has not occurred (S82:NO), then this means that notification is unnecessary, and the process ends. On the other hand, if it is determined in S82 that the error has occurred (S82:YES), then a duration of time is calculated by deducting the occurrence time stored in the administrator-status-information storage area 2262 (FIG. 10) from the present time, and the calculated duration of time is stored into the corresponding “duration” area of the administrator-status-information storage area 2262 (S83). Subsequently, it is determined whether or not the duration of time is equal to or greater than the value stored in the corresponding “quantity” area of the administrator-status-information storage area 2262. If not (S84:NO), this means that notification is unnecessary, and the process ends. On the other hand, if so (S84:YES), this means that notification is necessary. Then, the list preparation process that is the same process as in 837 of FIG. 15 is executed (S85). Values currently stored in the “occurrence time” area and the “duration” area of the administrator-status-information storage area 2262 are erased (S86). Subsequently, the process ends.

As described above, according to the present embodiment, occurrence and correction of an error in the printer 2 can be notified to one or more of the administrators by sending an error notification electronic mail or a restoration notification electronic mail. Because an electronic mail can be exchanged among different networks and is widely used communication system, using electronic mails is one of the beat notifying methods.

Because the administrator is notified of errors by electronic mails, it is particularly important not to notify the administrator of unnecessary information. That is, because the administrator cannot know the contents of the electronic mail until the administrator opens the electronic mail, the administrator needs to open a great and unnecessary number of electronic mails if unnecessary electronic mails are transmitted to notify the administrator of unnecessary information. However, according to the present embodiment, the administrator can receive only requested information, such problems can be overcome and burden on the administrator can be reduced.

Further, because undelivered electronic mails are temporarily stored in the mail server terminal device 5, this places a great burden on the mail server terminal device 5. Reducing the number of electronic mails to be transmitted to the administrator's terminal 3 decreases such a burden on the mail server terminal device S.

Also, each administrator can select optimum one of notification conditions of “OFF” (not notify), “ever time” (notify every time an error occurs). “times” (notify once every certain times), and “minutes” (notify if an error has not been fixed for minutes) for each of a plurality of error types. Therefore, the administrator can select which one or ones of error types the administrator wishes to be notified of. Further, if the administrator selects the “times” or “minutes”, the administrator can also select desired number of times or duration of time. Therefore, it is possible to distinguish a status in which “a cover is left open” and a status in which “a cover is opened temporarily” by selecting the “minutes” for an error “COVER OPEN”, for example. Thus, an error notification mail will not be sent even if a cover iv opened temporarily in order to remove sheet jam or even if a sheet feed tray is pulled out temporarily in order to supplement recording sheets. In other words, an error notification mail is not sent to the administrator every time an error occurs unless the administrator wishes. Also, an error notification mail relating to an error which has been fixed immediately after the occurrence is not sent. Only information necessary for the administrator is notified.

The notification mail transmitted to the administrator includes details of a subject error and a notification condition of the subject error, as well as names, notification conditions, and occurrence status of other errors of which the administrator wishes to be notified. Thus, the administrator can confirm the notification condition of the subject error and can grasp occurrence status of errors other than the subject error.

The administrator can select whether or not to receive a restoration notification mail when an error is fixed. If the administrator wishes, a restoration notification mail is sent to notify that the error has been fixed regardless of whether or not a different error has occurred and not fixed yet. Also, the restoration notification mail notifies not only recovery from an error but also occurrence status of other errors. Thus, the administrator can easily grasp the status of each error. Also, when a plurality of errors have occurred simultaneously, the administrator can grasp which error was fixed and which error is not.

A notification mail relating to an error is automatically prepared and transmitted to the administrator's terminal 3 when a printer status (Status of error) meets a predetermined notification condition. Therefore, the administrator can receive error information of the printer 2 under a condition preferable for the administrator.

Because it is possible to set the notification conditions for each of a plurality of administrators, an optimum condition can be set for each administrator.

Because the administrator on the administrator's terminal 3 sets the notification settings through the Web page, the administrator can easily perform the settings even if the administrator's terminal 3 is located away from the printer 2 and regardless of the structure of the printer 2. Also, because the Web browser is widely used, there is no need for the administrator to install special software or the like for performing such settings.

While the invention has been described in detail with reference to specific embodiments thereof, it would be apparent to those skilled in the art that many modifications and variations may be made therein without departing from the spirit of the invention, the scope of which is defined by the attached claims.

For example, the notification mail does not necessarily include a URL for displaying a notification setting screen, an administrator URL, and an IP address of the printer 2.

The network 1 is not limited to a wired structure but may be a wireless structure. The network 1 could be a Local Area Network (LAN), Wide Area Network (WAN), or the like.

The method for notifying an administrator of errors is not limited to an electronic mail. Any other method, such as a pop-up message according to an instant messenger, can be used as long as a message can be delivered to remote administrators individually.

Although the notification conditions are set for each of the administrators, the notification conditions can also be set for users, so that notification mails can be delivered to the users.

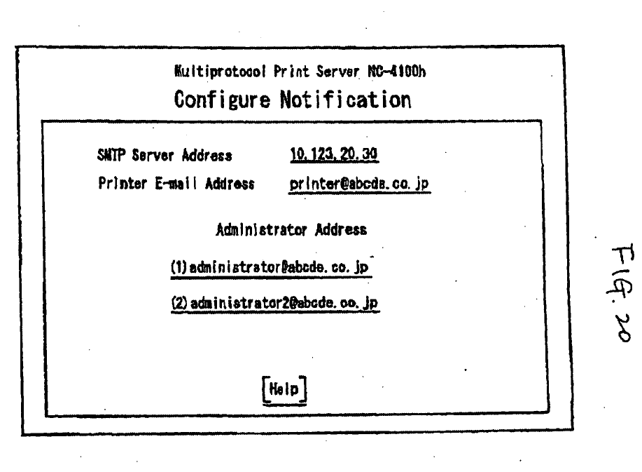

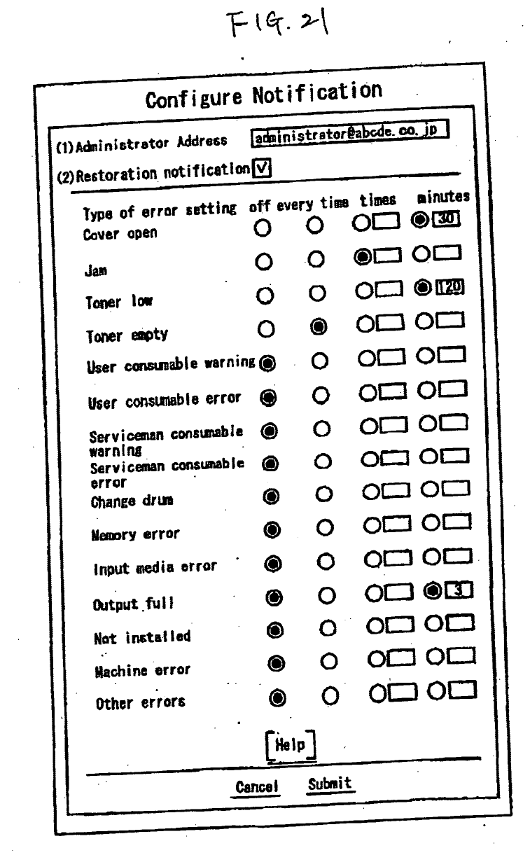

Although the administrator of the above embodiment performs the notification settings on the Web page provided by the Web server 223 of the printer 2, this is not a limitation of the present invention. For example, it is possible to install a notification setting software in the administrator's terminal 3, enabling the administrator to perform the settings using the notification setting software. FIGS. 20 and 21 shows examples of notification setting screens displayed on the monitor 31 according to such a notification setting program.

1. A network system comprising:
a network terminal; and
a terminal device connected to the network terminal,
wherein
the network terminal includes:
an error detection unit that detects an error;
a first memory that stores status of the error;
a second memory that stores a notification condition;
a judgment unit that judges whether or not the status of the error meets the notification condition; and
a notify unit that notifies the terminal device of the status of the error only when the judgment unit judges that the status of the error meets the notification condition.

2. The network system according to claim 1, wherein the terminal device includes a setting unit that sets the notification condition.

3. The network system according to claim 1, wherein the notify unit includes a mail preparation unit that prepares an electronic mail notifying of the status of the error only when the judgment unit judges that the status of the error meets the notification condition and a mail transmitting unit that transmits the electronic mail to the terminal device, and the terminal device includes a receiving unit that receives the electronic mail.

4. The network system according to claim 3, wherein the terminal device includes a setting unit that sets the notification condition and information necessary for the mail transmitting unit to transmit the electronic mail to the terminal device.

5. The network system according to claim 2, wherein the network terminal further includes a selection unit that selects at least one of a plurality of error types, and the judgment unit judges whether or not the error is of the selected error type, and the notify unit notifies the terminal device of the status of the error only when the error is judged of the selected error type.

6. The network system according to claim 5, wherein the terminal device includes a setting unit that sets the notification condition.

7. The network system according to claim 1, wherein the notification condition is a number of times of error occurrence.

8. The network system according to claim 7, wherein the terminal device includes a setting unit that sets the number of times of error occurrence as the notification condition.

9. The network system according to claim 1, wherein the notification condition is a duration of time for which the error has not been fixed.

10. The network system according to claim 9, wherein the terminal device includes a setting unit that sets the duration of time as the notification conditions.

11. The network system according to claim 1, wherein the network terminal further includes a setting unit that enables a user to set a desired notification condition.

12. The network system according to claim 11, wherein the setting unit of the network terminal includes:
an information preparing unit that prepares information for displaying a Web page that enables the user to set a desired notification condition;
a server that provides the information to te terminal device when requested by the terminal device; and
a storing unit that stores the notification condition set by the user into the second memory.

13. The network system according to claim 12, wherein the terminal device further includes a display unit that displays the Web page based on the information provided by the server of the network terminal and an input unit through which the user sets a desired notification condition on the Web page.

14. The network system according to claim 11, wherein the setting unit enables the user to select one of a plurality of notification conditions, which includes at least one of a number of times of error occurrence and a duration of time for which the error has not been fixed.

15. The network system according to claim 11, wherein the network terminal is connected to a plurality of terminal devices, and the setting unit enables the user to set a desired notification condition for each of the terminal devices.

16. The network system according to claim 15, wherein each of the terminal devices has an electronic mail address, and the setting unit enables the user to identify each of the terminal devices by the corresponding electronic mail address.

17. The network system according claim 16, wherein the notify unit includes a mail preparation unit that prepares an electronic mail notifying of the status of the error only when the judgment unit judges that the status of the error meets at least one of the notification conditions and a mail transmitting unit that transmits the electronic mail to at least one of the electronic mail addresses of the terminal devices corresponding to the at least one of the notification conditions.

18. The network system according claim 1, wherein:
the second memory stores a plurality of notification conditions each for a corresponding one of a plurality of error types;
the judgment unit judges whether or not the status of the error meets a corresponding one of the notification conditions;
the network terminal further includes a selection unit that selects at least one of the plurality of error types; and
the notify unit notifies of current status of another error of the selected error type when notifying of the status of the error.

19. The network system according to claim 18, wherein the notify unit further notifies of the notification condition of the another error when notifying of the status of the error.

20. The network system according to claim 18, wherein the notify unit further notifies the notification condition of the error when notifying of the status of the error.

21. The network system according to claim 1, wherein the error detection unit further detects an error correction when the error was fixed, and the notify unit notifies the terminal device of the error correction.

22. A network terminal connected to at least one, terminal device, the network terminal comprising:
an error detection unit that detects an error;
a first memory that stores status of the error;
a second memory that stores a notification condition;
a judgment unit that judges whether or not the status of the error meets the notification condition; and
a notify unit that notifies the terminal device of the status of the error when the judgment unit judges that the status of the error meets the notification condition.

23. The network terminal according to claim 22, wherein the notify unit includes a mail preparation unit that prepares an electronic mail notifying of the status of the error when the judgment unit judges that the status of the error meets the notification condition and a mail transmitting unit that transmits the electronic mail to the terminal device.

24. The network terminal according to claim 22, further comprising a selection unit that selects at least one of a plurality of error types, wherein the judgment unit judges whether or not the error is of the selected error type, and the notify unit notifies the terminal device of the status of the error only when the error is judged of the selected error type.

25. The network terminal according to claim 22, further comprising a setting unit that enables a user to set a desired notification condition.

26. The network system according to claim 25, wherein the setting unit of the network terminal includes:
an information preparing unit that prepares information for displaying a Web page that enables the user to set a desired notification condition;
a server that provides the information to the terminal device when requested by the terminal device; and
a storing unit that stores the notification condition set by the user into the second memory.

27. The network terminal according to claim 25, wherein the setting unit enables the user to select one of a plurality of notification conditions, which includes at least one of a number of times of error occurrence and a duration of time for which the error has not been fixed.

28. The network terminal according to claim 25, wherein the setting unit enables the user to set a desired notification condition for each of a plurality of terminal devices.

29. The network terminal according to claim 28, wherein each of the terminal devices has an electronic mail address, and the setting unit enables the user to identify each of the terminal devices by the corresponding electronic mail address.

30. The network terminal according claim 29, wherein the notify unit includes mail preparation unit that prepares an electronic mail notifying of the_status of the error only when the judgment unit judges that the status of the error meets at least one of the notification conditions and a mail transmitting unit that transmits the electronic mail to at least one of the electronic mail addresses of the terminal devices corresponding to the at least one of the notification conditions.

31. The network terminal according claim 22, further comprising a selection unit that selects at least one of a plurality of error types, wherein the second memory stores a plurality of notification conditions each for a corresponding one of the plurality of error types, the judgment unit judges whether or not the status of the error meets a corresponding one of the notification conditions, and the notify unit further notifies current status of another error of the selected error type when notifying of the status of the error.

32. The network terminal according to claim 31, wherein the notify unit further notifies of the notification condition of the another error when notifying of the status of the error.

33. The network terminal according to claim 22, wherein the notify unit further notifies of the notification condition of the error when notifying of the status of the error.

34. The network terminal according to claim 22, wherein the error detection unit further deteata an error correction when the error was fired, and the notify unit further notifies the terminal device of the error correction.

35. A notifying method of notifying a terminal device of an error, the notifying method comprising the steps of:
a) detecting an error occurred at a network terminal;
b) storing status of the error into a first memory;
c) judging whether or not the status of the error meets a notification condition stored in a second memory, and
d) notifying the terminal device of the status of the error when the status of the error is judged to meet the notification condition in the step c).

36. The notifying method according to claim 35, wherein the notifying step d) includes the steps of e) preparing an electronic mail notifying of the status of the error only when the status of the error is judged to meet the notification condition in the step c) and f) transmitting the electronic mail to the terminal device.

37. The notifying method according to claim 35, further comprising the steps of g) selecting at least one of a plurality of error types and h) judging whether or not the error is of the error type selected in the step g), wherein the status of the error is notified of in the step d) only when the error is judged of the selected error type in the step h).

38. The notifying method according to claim 35, herein the notification condition is a number of times of error occurrence.

39. The notifying method according to claim 35, wherein the notification condition is a duration of time for which the error has not been fixed.

40. The notifying method according to claim 35, further comprising the step of i) enabling a user to set a desired notification condition.

41. The notifying method according to claim 40, wherein the stop i) includes the steps of J) transmitting information from the network terminal to the terminal device, k) displaying a Web page on a display of the network device based on the information, the Web page enabling the user to set a desired notification condition, and 1) storing the notification condition set by the user into the second memory.

42. The notifying method according to claim 35, further comprising the step of m) enabling a user to select one of a plurality of notification conditions, which includes at least one of a number of times of error occurrence and a duration of time for which the error has not been fixed.

43. The notifying method according to claim 35, further comprising the step of n) enabling a user to set a desired notification condition for each of a plurality of terminal devices.

44. The notifying method according to claim 43, wherein in the step of n), the user is enabled to identify each of the terminal devices by a corresponding electronic mail address.

45. The notifying method according claim 44, wherein the notifying step d) includes the steps of preparing an electronic mail notifying of the status of the error only when the status of the error is judged to meet at least one of the notification conditions and transmitting the electronic mail to at least one of the electronic mail addresses of the terminal devices corresponding to the at least one of the notification conditions.

46. Thr notifying method according claim 35, further comprising o) selecting at least one of a plurality of error types, wherein in the step C) it is judged whether or not the status of the error meets a corresponding one of a plurality of notification conditions stored in the second memory, and in the step d) current status of another error of the selected error type is also notified of.

47. The notifying method according to claim 46, wherein in the step d) the notification condition of the another error is also notified of.

48. The notifying method according to claim 35, wherein in the step d) the notification condition of the error is also notified of.

49. The notifying method according to claim 35, further comprising the steps of p) detecting an error correction when the error was fixed and q) notifying the terminal device of the error correction.
